(19) United States
(12) Patent Application Publication
(10) Pub. No.: US 2017/0071333 A1
(43) Pub. Date: Mar. 16, 2017

(54) Portable Tilted Table for Use With Cell Phones, Tablets, Pads, Electronic Books or Similar Electronic Devices

(71) Applicant: John Jefferson Fox, III, Magnolia, TX (US)

(72) Inventor: John Jefferson Fox, III, Magnolia, TX (US)

(21) Appl. No.: 15/263,494

(22) Filed: Sep. 13, 2016

Related U.S. Application Data
(60) Provisional application No. 62/218,670, filed on Sep. 15, 2015.

(51) Int. Cl. A47B 23/04; H05K 5/02; F16M 11/22

(52) U.S. Cl. CPC A47B 23/042; F16M 11/22; H05K 5/0204

(57) ABSTRACT

A portable tilted table for cell phones, tablets, pads, electronic books or similar electronic devices is shown. The portable tilted table rests on a flat surface with the electronic device resting on the tilted surface with a footrest preventing the electric device from sliding off the tilted surface. This allows the user to use one hand for the electronic device, having the other hand free for other tasks. A notch in the footrest allows the electronic device to be charged while resting on the tilted surface.

### CROSS-REFERENCE TO RELATED APPLICATIONS

This utility patent application claims priority to U.S. Provisional Application for Patent Ser. No. 62/218,670, filed Sep. 15, 2015, entitled “Tilt.”

### BACKGROUND OF THE INVENTION

1. Field of the Invention

The present invention relates to a portable table for cell phones or similar electronic devices and, more particularly, a portable tilted table made of foam or similar material on which the electronic device can rest while in use.

2. Description of the Prior Art

In today's world, cell phones are used by just about anyone at just about any location. However, when sending a text message, one hand has to be used to hold the cell phone or electronic device, while the other hand sends the text message. The same is true when browsing using the electronic device. One hand must hold the electronic device, while the other hand does the browsing.

In today's world of multi-tasking, many people do two things at once. For example, a person might be eating a meal and would like to at the same time to review messages or send a text message. If both hands are required for the electronic device, it is not possible to eat at the same time. However, if there is a small, portable tiltable table upon which the electronic device can rest, one hand can be used to eat while the other hand types out an electronic message on the portable electronic device. The same is true when browsing on a cell phone or electronic device.

There is a need for a small portable table that will hold the cell phone or electronic device in position so that one hand can be used for scanning or sending a text message. The other hand is free to do other functions, such as holding a child or eating a meal.

### SUMMARY OF THE INVENTION

It is an object of the present invention to provide a portable table for cell phones or electronic devices.

It is still another object of the present invention to provide a portable tilted table made of foam or similar material on which an electronic device can rest while in use.

It is yet another object of the present invention to provide a small, portable table for cell phones or similar electronic devices, which table is made of flexible, polyurethane foam on which the cell phones or electronic device can rest while in use.

It is another object of the present invention to provide a portable tilted table for cell phones which may be placed on a flat surface and has a lower lip with a notch cut therein for recharging of the cell phones while on the table.

Flexible polyurethane foam is cut so that a tilted surface is provided on which a cell phone can rest while in use. A lower footrest prevents the cell phone from sliding off of the tilted surface. A person can use the electronic device located on the portable tilted table with one hand with the other hand being free for other tasks.

The portable tilted table may be made of flexible polyurethane foam that has a density of between 1.2 lbs. to 2 lbs. per cubic foot with an initial load deflection of between 36 to 40 lbs. The polyurethane foam is cut vertically and horizontally, the final cut being with a steel ruled die.

If logo, trademark or other indicia is to be put on a table, a screen imprint using Plastisol ink which cures between 15 to 18 seconds at 350° F. may be used.

### DESCRIPTION OF THE DRAWINGS

FIG. 1 is a perspective view of the portable tilted table for use with cell phones or similar electronic devices.

FIG. 2 is an elevated side view of FIG. 1.

FIG. 3 is environmental view showing the portable tilted table in use.

### DESCRIPTION OF THE PREFERRED EMBODIMENT

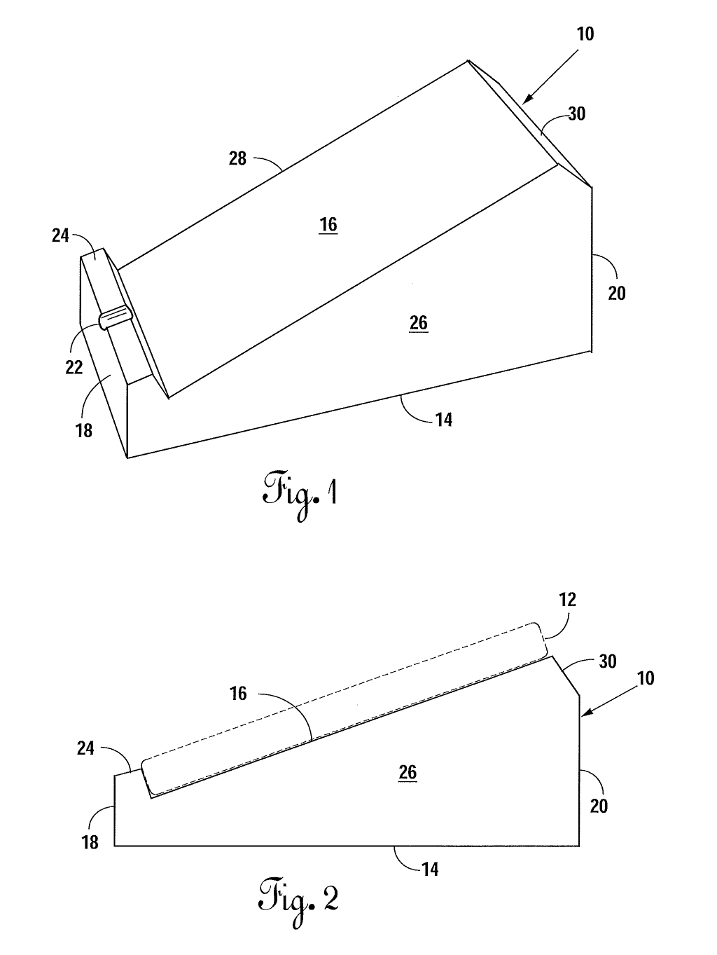

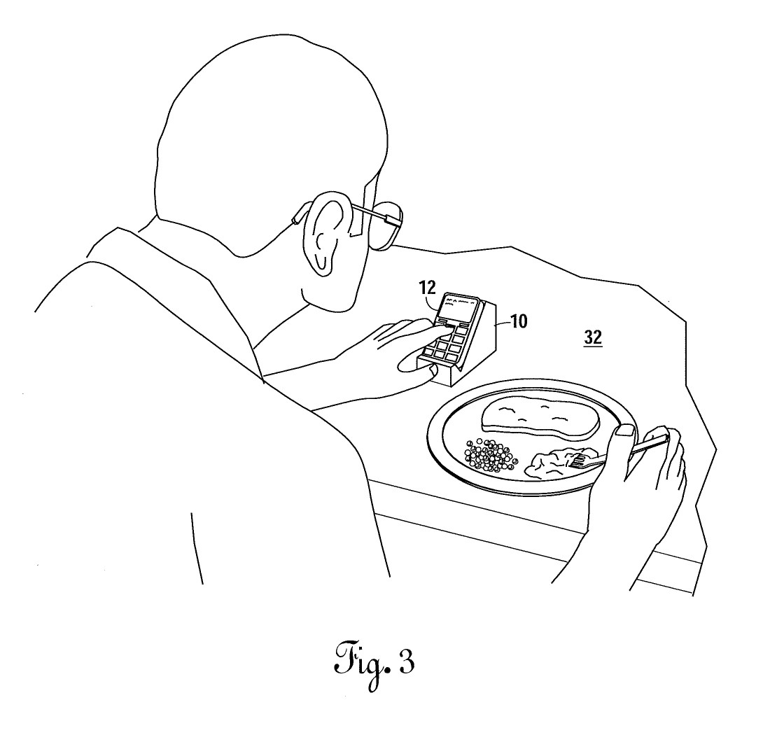

Referring to FIGS. 1 and 2 in combination, a portable tilted table 10 is shown for holding a cell phone 12 or similar electronic device. The portable tilted table 10 has a flat bottom 14 suitable for resting on a table or similar flat structure. The cell phone 12 rests on a tilted surface 16, which extends from the foot 18 to the head 20 of the portable tilted table 10. The foot 18 has a notch 22 cut therein so that as the cell phone 12 rests on the tilted surface 16, the cell phone 12 can be recharged by a cord (not shown) extending through notch 22 of footrest 24. The footrest 24 prevents the cell phone 12 from sliding off the tilted surface 16.

Extending from the foot 18 to the head 20 of the portable tilted table 10 is side 26, which is a flat surface. Backside 28 is identical to and parallel to side 26. Between the tilted surface 16 and the head 20 is a sloped upper surface 30.

FIG. 3 shows a typical environment use of the portable tilted table 10 with the cell phone 12 located thereon. The user may be eating a meal with one hand while using the other hand to either browse the cell phone 12 or send a text message.

By making the portable tilted table 10 of flexible polyurethane foam, it will adhere to the top 32 of the table. It has been found that a flexible, polyurethane foam that has a density of between 1.2 lbs. to 2 lbs. per cubic foot is ideal. A typical initial load deflection of between 36 to 40 lbs. should be used for the polyurethane foam. The polyurethane foam which comes in huge blocks is cut vertically and horizontally with a final cut being with s steel ruled die.

In case the cell phone 12 needs to be recharged while in use, it may be plugged in with the notch 22 allowing the cord for the recharger to extend there through to the cell phone 12.

It has been found that the slope of the tilted surface 16 is ideal when between 15° to 45°. For a typical cell phone, the flat bottom 14 of the portable tilted table 10 should be approximately 5 inches long. The head 20 should extend approximately 3.75 inches above the flat bottom 14. The width of the portable tilted table 10 can vary between 4 to 12 inches, depending upon the electronic device being held by the portable tilted table 10.

While the portable tilted table 10 is shown as made from polyurethane foam, the portable tilted tables 10 can be made from polystyrene, plastic composites, solid or laminated wood.

While the portable titled table 10 has been described in connection with cell phone 12, it may hold other portable electronic devices such as tablets, pads, or even smaller computers. The object is for the portable tilted table 10 to provide easy access to the electronic device by one hand while keeping the other hand free. The free hand may be used for anything else. Young parents find this convenient when holding a child.

Because the portable tilted table 10 is very economical to make, companies may want to provide give-away items of the portable tilted table 10. If that is the case, the company logo may be printed on the tilted surface 16, 20, 26 and 28. The printing of the company logo, name or indicia on the tilted surface 16 can be applied by screen printing with a Plastisol ink that would cure in 15 to 18 seconds at 350° F.

An ideal use of the portable titled table 10 is in the kitchen where the electronic device would set thereon. The electronic device could then be used to either locate recipes or play music while the individual user performs various tasks in the kitchen.

For larger pads and tablets, the portable tilted table 10 can be made wider than the portable tilted table 10 shown in FIGS. 1 through 3.

What I claim is:

1. A table for an electronic device such as cell phones, pads, tablets or electronic books so the user can have one free hand to perform other tasks while one hand operates the electronic device with the table being located on a flat surface, the table comprising:
a block of flexible polyurethane foam;
a flat bottom of said block for resting on said flat surface;
a foot and a head of said block;
a tilted surface extending upwardly from said foot to said head of said block, said tilted surface being approximately the length of said electronic device;
a footrest at said foot of said block to prevent said electronic device from sliding off said tilted surface while in use;
sides of said block generally perpendicular to said foot and said head, said sides being generally parallel to each other, said sides being spaced apart approximately the width of said electronic device; and
a notch in said foot rest so that said electronic device can be charged while resting on said tilted surface.

2. The table for said electronic device as recited in claim 1, wherein said tilted surface is tilted at a range of 15° to 45°.

3. The table for said electronic device as recited in claim 2, wherein said flexible polyurethane foam has a density of between 1.2 lbs. to 2 lbs. per cubic foot and an initial load deflection of between 36 to 40 lbs.

4. The table for said electronic device as recited in claim 3 having indices painted thereon using screen printing with an ink that dries rapidly when heated.
